(19) United States
(12) Patent Application Publication
(10) Pub. No.: US 2012/0325986 A1
(43) Pub. Date: Dec. 27, 2012

(54) SUPPORTING ASSEMBLY FOR ELECTRONIC DEVICE

(75) Inventors: Yun-Lung CHEN, Tu-Cheng (TW); Chung CHAI, Tu-Cheng (TW); Da-Long SUN, Wuhan City (CN)

(73) Assignees: HON HAI PRECISION INDUSTRY CO., LTD., Tu-Cheng (TW); HONG FU JIN PRECISION INDUSTRY (WuHan) CO., LTD., Wuhan City (CN)

(21) Appl. No.: 13/425,384

(22) Filed: Mar. 20, 2012

(30) Foreign Application Priority Data
Jun. 22, 2011 (CN) 201110168808.7

(51) Int. Cl. H05K 7/00

(52) U.S. Cl. 248/122.1

(57) ABSTRACT

A supporting assembly for an electronic device, includes a mounting piece and a stand. The mounting piece is mounted on the electronic device. The mounting piece includes a connection piece which defines a pivot hole. The stand includes a shaft. A friction piece is mounted on the shaft and adapted to rotate together with the shaft. The shaft is inserted in the pivot hole and rotatable in the pivot hole. The friction piece provides a firm and stable, but adjustable, base around which the stand can be positioned as required.

### BACKGROUND

1. Technical Field

The present disclosure relates to supporting assemblies, more particularly, to a supporting assembly for supporting an electronic device.

2. Description of Related Art

Electronic devices such as monitors and tablet computers may be supported by supporting assemblies to stand on a desk for conveniently showing contents therein. However, the supporting assemblies of related art usually have complex structures and may require many components to assemble.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded and isometric view of a supporting assembly of an embodiment and an electronic device.

FIG. 2 is another exploded and isometric view of the supporting assembly of FIG. 1.

FIG. 3 is an assembled view of the supporting assembly of FIG. 2.

FIG. 4 is an assembled view of the supporting assembly and the electronic device of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

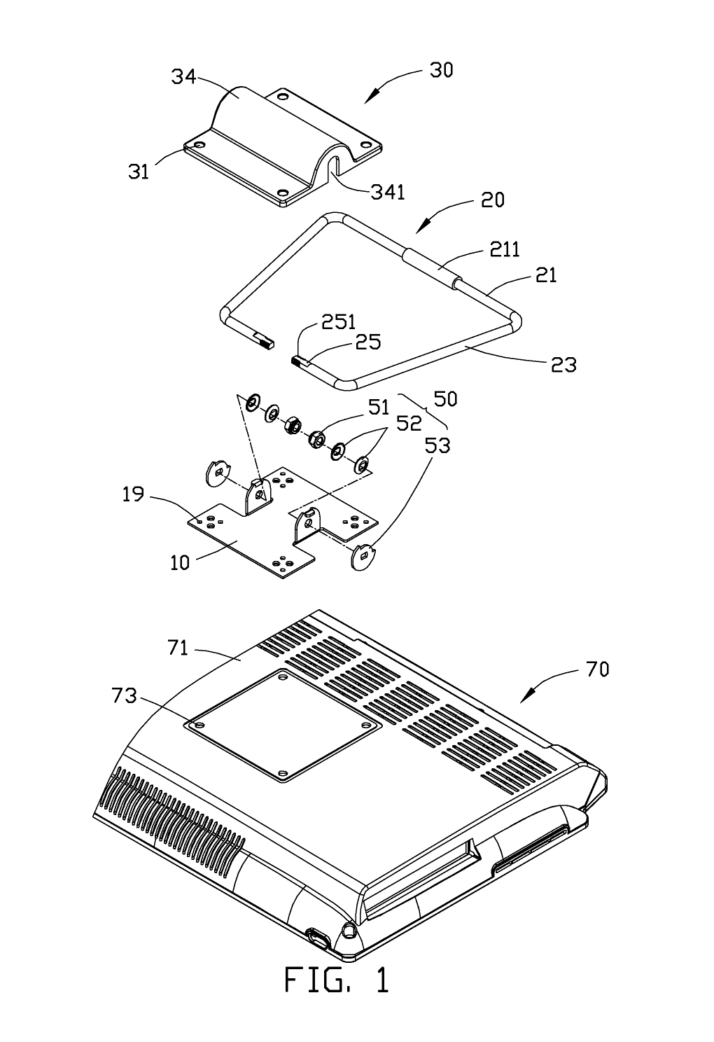

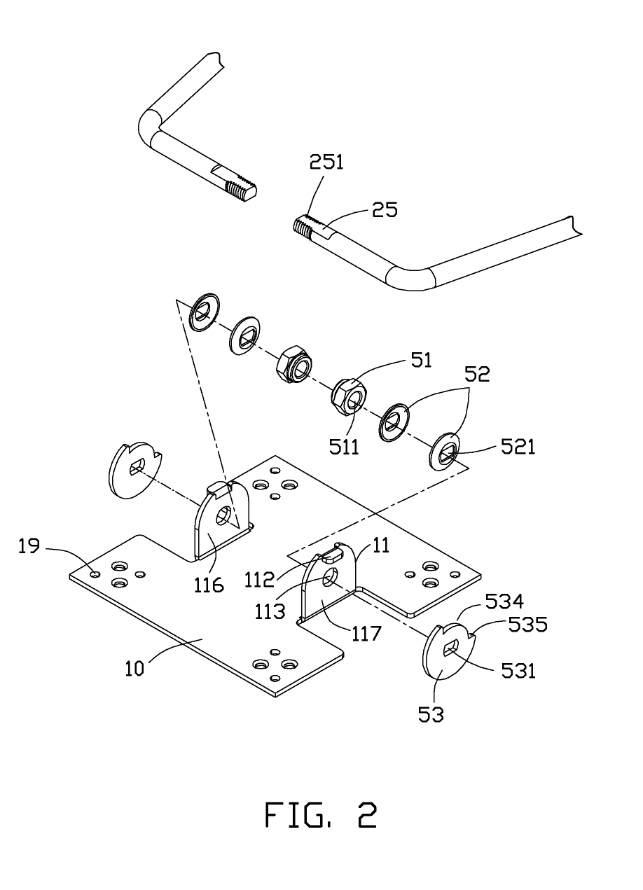

Referring to FIGS. 1 and 2, a supporting assembly in accordance with an embodiment, is used to support an electronic device 70. The supporting assembly includes a mounting piece 10, a stand 20, a cover 30 and two pivot assemblies 50. In one embodiment, the electronic device 70 is a monitor.

The mounting piece 10 is generally square. Each of four corners of the mounting piece 10 defines a first mounting hole 19. A pair of connection pieces 11 are uprightly located on the mounting piece 10. Each of the pair of connection pieces 11 includes a first side 117 and a second side 116. The two second sides 116 face each other. A guiding piece 112 is perpendicularly connected to a top edge of each of the pair of connection pieces 11. The guiding piece 112 extends from the first side 117 of each of the pair of connection pieces 11. Each of the pair of connection pieces 11 defines a pivot hole 113.

Each of the two pivot assemblies 50 includes a fastener 51, two gaskets 52, and a friction piece 53. The fastener 51 defines a fixing hole 511. Outside of the friction piece 53 is rough for generating friction force. A center portion of the friction piece 53 defines a double-D shaped first through hole 531. A recess 534 is defined in a peripheral portion of the friction piece 53. Each side of the recess 534 forms a barrier side 545. Each of the two gaskets 52 defines a double-D shaped second through hole 521.

The stand 20 is formed by a bent rod. The stand 20 includes a base 21. A skidproof pad 211 is set around the stand 20. Opposite ends of the base 21 extend obliquely to form a pair of supporting arms 23. Free ends of the pair of supporting arms 23 extend towards each other to form a pair of shafts 25. The pair of shafts 25 are parallel to the base 21. A distal end of each of the pair of shafts 25 is a fixing portion 251. A cross section of the fixing portion 251 is double-D shaped corresponding to the first through hole 531 and second through hole 521. A plurality of screw threads is formed on the fixing portion 251.

Each of four corners of the cover 30 defines a second mounting hole 31. A central portion of the cover 30 is protruded to form a receiving portion 34. A receiving space 341 is defined in the receiving portion 34.

The electronic device 70 includes a rear plate 71. The rear plate 71 defines four third mounting holes 73.

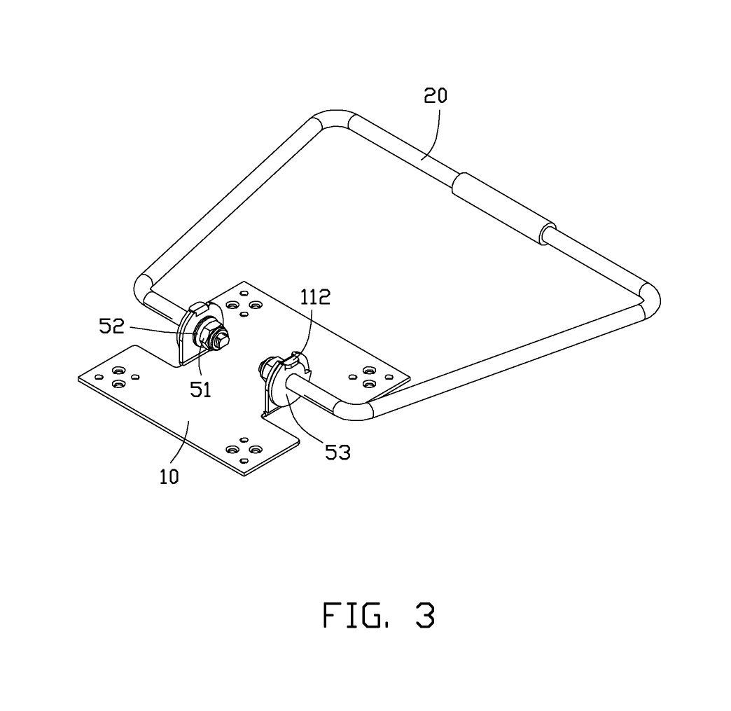

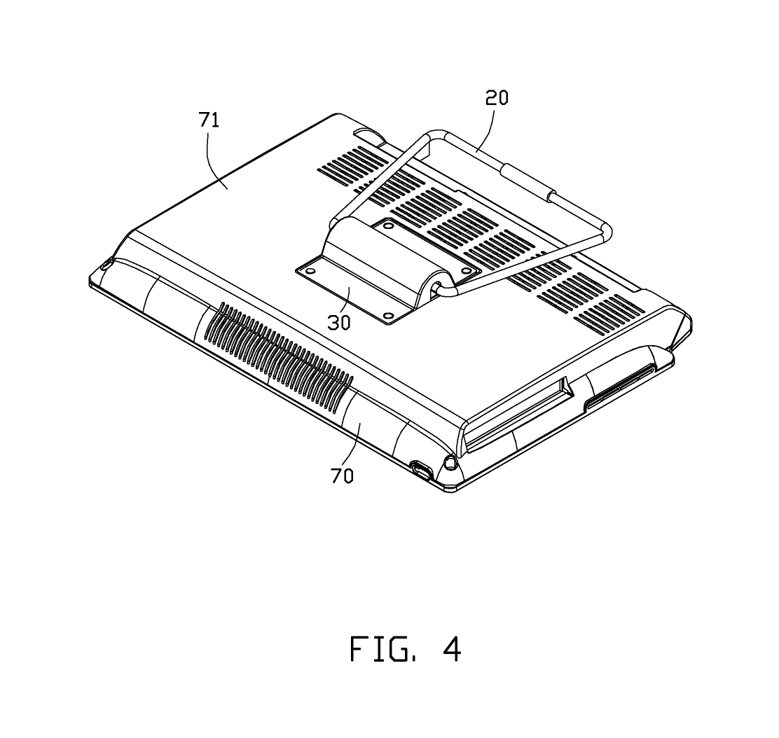

Referring to FIGS. 1 to 4, in assembly, each of the two gaskets 52 is placed on the second side 116 of each of the pair of connection pieces 11. The second through hole 521 is aligned to the pivot hole 113. The friction piece 53 is placed on the first side 117 of each of the pair of connection pieces 11. The first through hole 531 is aligned to the pivot hole 113. The guiding piece 112 is received in the recess 534.

Then, the fixing portion 251 of each of the pair of shafts 25 is in turn inserted in the first through hole 531, the pivot hole 113, and the second through hole 521. The fixing portion 251 is then fixed in the fixing hole 511 of the fastener to mount each of the two pivot assemblies 50 and the stand 20 on the mounting piece 10. Each of the two gaskets 52 is firmly pressed against the second side 116. The friction piece 53 is firmly pressed against the first side 117. Because shaped of the first through hole 531, the second through hole 521, and the cross section of the fixing portion 251 are double-D shape, the two gaskets 52 and the friction piece 53 can rotate together with the pair of shafts 25. When the pair of shafts 25 rotate in the pivot hole 113, the friction piece 53 is rotated relative to the first side 117, and friction force locates the stand 20 in a fixed position at the end of any rotation. Further, the pair of shafts 25 rotate until a barrier side 535 abuts the guiding piece 112.

The pair of shafts 25 and the pair of connection pieces 11 are placed in the receiving space 341 of the cover 30. The mounting piece 10 is placed on the rear plate 71 of the electronic device 70. The first mounting holes 19 and the second mounting holes 31 are aligned to the third mounting holes 73. A plurality of screws is secured in the first mounting holes 19, the second mounting holes 31, and the third mounting holes 73. So, the supporting assembly is pivotally mounted on the electronic device 70.

In use, the base 21 of the stand 20 is located on a desk. The skidproof pad 211 can prevent the base 21 from sliding. The pair of shafts 25 can rotate relative to the electronic device 70 to adjust a viewing angle of the electronic device. Friction force between the friction piece 53 and the first side 117 holds the electronic device 70 in different inclined positions. Further, each of the barrier sides 535 abuts the guiding piece 112 to prevent over-rotation.

In the embodiment, the first through hole 531 shape can be other shapes not based on a circle, as long as the fixing portion 251, the two gaskets 52 and the friction piece 53 are forced to rotate together.

It is to be understood, however, that even though numerous characteristics and advantages of the embodiments have been set forth in the foregoing description, together with details of the structure and functions of the embodiments, the disclosure is illustrative only, and changes may be made in detail, especially in the matters of shape, size, and arrangement of parts within the principles of the invention to the full extent indicated by the broad general meaning of the terms in which the appended claims are expressed.

What is claimed is:

1. A supporting assembly for an electronic device, comprising:
a mounting piece mounted on the electronic device, the mounting piece comprising a connection piece, the connection piece defining a pivot hole; and
a stand comprising a shaft, a friction piece mounted on the shaft and adapted to rotate together with the shaft, the shaft being inserted into the pivot hole and rotatable in the pivot hole, and the friction piece being pressed against the connection piece thereby generating friction forces between the friction piece and the connection piece.

2. The supporting assembly of claim 1, wherein the connection piece comprises a guiding piece, and the friction piece defines a recess configured to receive the guiding piece, the recess defines two barrier sides, and the shaft is configured to rotate until the guiding piece abuts one of the two barrier sides.

3. The supporting assembly of claim 2, wherein the recess is defined in a peripheral portion of the friction piece.

4. The supporting assembly of claim 1, wherein the a shape of a cross section of the shaft is non-circular, the friction piece defines a first non-circle hole, the shaft is inserted into the first non-circle hole to secure the friction piece on the shaft.

5. The supporting assembly of claim 1, wherein the stand comprises a base, one end of the base extends obliquely to form a supporting arm, the supporting arm extends to form the shaft, and the shaft is parallel to the base.

6. The supporting assembly of claim 5, wherein a skidproof pad is set around the stand.

7. The supporting assembly of claim 1, further comprising a gasket, wherein the connection piece comprises a first side and a second side opposite to the first side, the friction piece is pressed against the first side, and the gasket is pressed against the second side.

8. The supporting assembly of claim 7, wherein a shape of a cross section of the shaft is non-circular, the gasket defines a second non-circle hole, the shaft is inserted into the second non-circle hole to secure the gasket on the shaft.

9. The supporting assembly of claim 1, further comprising a cover, wherein the cover defines a receiving space, the connection piece and the shaft are received in the receiving space, and the cover is mounted on the electronic device.

10. A supporting assembly, comprising:
a mounting piece comprising a connection piece, the connection piece comprising a first side and a second side opposite to the first side, a pivot hole defined between the first side and the second side; and
a stand comprising a shaft, a friction piece and a gasket secured on the shaft, and the friction piece and the gasket adapted to rotate together with the shaft; the shaft being inserted into the pivot hole, the first side being pressed against the friction piece, the second side being pressed against the gasket;
wherein the shaft is adapted to rotate in the pivot hole, and friction piece is pressed against the connection piece thereby generating friction forces between the friction piece, and the connection piece.

11. The supporting assembly of claim 10, wherein the connection piece comprises a guiding piece, and the friction piece defines a recess configured to receive the guiding piece, the recess defines two barrier sides, and the shaft is configured to rotate until the guiding piece abuts one of the two barrier sides.

12. The supporting assembly of claim 11, wherein the recess is defined in a peripheral portion of the friction piece.

13. The supporting assembly of claim 10, wherein a shape of a cross section of the shaft is non-circular, the friction piece defines a first non-circle hole, the shaft is inserted into the first non-circle hole to secure the friction piece on the shaft.

14. The supporting assembly of claim 10, wherein the stand comprises a base, one end of the base extend obliquely to form a supporting arm, the supporting arm extends to form the shaft, and the shaft is parallel to the base.

15. The supporting assembly of claim 14, wherein a skidproof pad is set around the stand.

16. The supporting assembly of claim 10, wherein the friction piece is pressed against the first side, and the gasket is pressed against the second side.

17. The supporting assembly of claim 16, wherein the a shape of a cross section of the shaft is non-circular, the gasket defines a second non-circle hole, the shaft is inserted into the second non-circle hole to secure the gasket on the shaft.

18. The supporting assembly of claim 10, further comprising a cover, wherein the cover defines a receiving space, the connection piece and the shaft are received in the receiving space, and the cover is mounted on the electronic device.
